(19) United States
(12) Patent Application Publication
(10) Pub. No.: US 2026/0084249 A1
(43) Pub. Date: Mar. 26, 2026

(54) HEATING UNIT AND SOLAR CELL REPAIRING APPARATUS HAVING THE SAME

(71) Applicant: ADDFA CO., LTD., Cheonan-si Chungcheongnam-do (KR)

(72) Inventors: Hyung Jin PARK, Osan-si Gyeonggi-do (KR); Ki Young SHIN, Cheongju-si Chungcheongbuk-do (KR); Jae Hun LEE, Hwaseong-si Gyeonggi-do (KR); Sang Min LEE, Cheonan-si Chungcheongnam-do (KR)

(73) Assignee: ADDFA CO., LTD., Cheonan-si Chungcheongnam-do (KR)

(21) Appl. No.: 18/897,123

(22) Filed: Sep. 26, 2024

(51) Int. Cl. B23K 28/00; H01L 21/68; H01L 31/18

(52) U.S. Cl. CPC B23K 28/00; H10F 71/00; H10P 72/50

(57) ABSTRACT

Provided a heating unit for a solar cell including a housing forming an exterior, a plurality of air heaters arranged in a first direction in the housing, and a heating block disposed on one side of the housing and configured to spray gas heated by the plurality of air heaters to the outside in a concentrated manner, wherein the heating block includes a plurality of inlet ports formed at positions corresponding to the plurality of air heaters, and a plurality of spray ports in communication with the plurality of inlet ports, spaced apart from each other predetermined intervals, and each having a diameter smaller than a diameter of each of the inlet ports.

### BACKGROUND

### 1. Field

Embodiments of the present disclosure relate to a heating unit and a solar cell repairing apparatus having the same.

### 2. Description of the Related Art

Recently, interest in renewable energy has been growing, and accordingly, solar cells that directly produce electricity by converting sunlight energy and photovoltaic power generation using these solar cells have been gaining attention.

In general, a solar cell includes a semiconductor substrate forming a p-n junction, an emitter, a back surface field (BSF) layer, and electrodes connected to the semiconductor substrate at an interface between the emitter and the BSF layer. A solar cell module used in photovoltaic power generation is manufactured by arranging a plurality of solar cells with the above-described configuration in a line, electrically connecting adjacent solar cells with wires to form a string of solar cells as a single bundle unit, and then arranging a plurality of strings and electrically connecting the arranged strings. Here, a common method for electrically connecting the plurality of solar cells involves using a copper ribbon coated with solder, and the copper ribbon is bonded to the electrodes provided on each solar cell, thereby connecting multiple adjacent solar cells.

Meanwhile, when a defective cell is included in the solar cell module, it may cause a decrease in overall output or malfunction, making it essential to perform repair work to replace the defective cell. The repair work involves removing only the defective cell from the string of solar cells, placing a new solar cell in the position of the corresponding defective cell, and then electrically connecting adjacent solar cells to the new solar cell. To briefly describe the process of repair work, heat is first applied to an area of electrodes of the defective cell to release the wire connection, after which the wires are cut, and the defective cell is removed. Next, a new solar cell is placed, wires between the new solar cell and the adjacent solar cell are aligned, and then the wires are bonded to electrodes of the new solar cell to establish the connection of the new solar cell.

However, in traditional solar cell repair work, manual labor is unavoidable when removing a defective solar cell, resulting in increased work time, difficulty in performing precise work, and also causing further damage to the solar cell during the repair process.

### SUMMARY

Embodiments of the present disclosure aim to solve the above-described problems, and are directed to providing a heating unit capable of effectively heating an area of electrodes of a defective cell during solar cell repair work without damaging a solar cell.

Embodiments of the present disclosure are also directed to providing a repair apparatus capable of easily replacing a defective solar cell and significantly reducing the operation time.

However, these objects are only examples and the scope of the present disclosure is not limited thereby.

Additional aspects will be set forth in part in the description which follows and, in part, will be apparent from the description, or may be learned by practice of the presented embodiments of the disclosure.

According to an aspect of the present disclosure, there is provided a heating unit for a solar cell including a housing forming an exterior, a plurality of air heaters arranged in a first direction in the housing, and a heating block disposed on one side of the housing and configured to spray gas heated by the plurality of air heaters to the outside in a concentrated manner, wherein the heating block includes a plurality of inlet ports formed at positions corresponding to the plurality of air heaters, and a plurality of spray ports in communication with the plurality of inlet ports, spaced apart from each other predetermined intervals, and each having a diameter smaller than a diameter of each of the inlet ports.

In an embodiment of the present disclosure, the number of the inlet ports and the number of the spray ports may be different from each other.

In an embodiment of the present disclosure, the number of the spray ports may be greater than the number of the inlet ports.

In an embodiment of the present disclosure, the plurality of spray ports may be spaced apart from each other to correspond to separation distances of electrodes formed on one surface of a solar cell.

In an embodiment of the present disclosure, each of the spray ports may be formed to correspond in size to a size of each of the electrodes.

In an embodiment of the present disclosure, the heating unit may further include a cartridge heater extending in the first direction and inserted into the heating block.

In an embodiment of the present disclosure, the heating block may further include an accommodation space formed between the inlet ports and the spray ports, and the cartridge heater may be disposed adjacent to the accommodation space.

In an embodiment of the present disclosure, the cartridge heater may be provided as a plurality of cartridge heaters, and the plurality of cartridge heaters may be symmetrically disposed with respect to the accommodation space.

According to another aspect of the present disclosure, there is provided a solar cell repairing apparatus including a stage configured to support a solar cell module that may include a plurality of solar cells connected to each other by wires, a heating unit configured to heat an area of first electrodes of a defective cell in the solar cell module to separate some of the wires from the defective cell, and a cutting unit configured to cut wires that connect the defective cell to a good cell adjacent to the defective cell, wherein the heating unit includes a housing forming an exterior, a plurality of air heaters arranged in a first direction in the housing, and a heating block disposed on one side of the housing and configured to spray gas heated by the plurality of air heaters to the outside in a concentrated manner, wherein the heating block includes a plurality of inlet ports formed at positions corresponding to the plurality of air heaters, and a plurality of spray ports in communication with the plurality of inlet ports, spaced apart from each other predetermined intervals, and each having a diameter smaller than a diameter of each of the inlet ports.

In an embodiment of the present disclosure, the heating block may be spaced apart from the first electrodes by a predetermined distance and configured to spray the heated gas onto the area of the first electrodes.

In an embodiment of the present disclosure, the cutting unit may cut the wires, which are separated from the defective cell, at a position adjacent to the defective cell than the good cell.

In an embodiment of the present disclosure, a movement of the cutting unit may be controlled by a robot arm, and the robot arm may control the movement of the cutting unit so that the cutting unit approaches the defective cell in an oblique direction with respect to one surface of the defective cell during the cutting of the wires.

In an embodiment of the present disclosure, the solar cell repairing apparatus may further include an aligning unit configured to align wires between a solar cell replacing the defective cell and the good cell.

In an embodiment of the present disclosure, the aligning unit may include a mounting part mounted on a driving device, and a gripper part coupled to one end of the mounting part, wherein the gripper part may include a first gripper including a first guiding part having a preset first thickness, and a second gripper including a second guiding part that has a preset second thickness and moves relative to the first gripper, wherein the first thickness and the second thickness are determined according to a thickness of each of the wires.

Other aspects, features, and advantages other than those described above will become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view for describing a method of replacing a defective cell in a solar cell repairing apparatus according to an embodiment of the present disclosure;

FIG. 2 is a view for describing a method of replacing the defective cell in the solar cell repairing apparatus according to an embodiment of the present disclosure;

FIG. 3 is a view for describing the movement of a stage and a heating position of a heating unit;

FIG. 4 is a view for describing the movement of the stage and a cutting position of a cutting unit;

FIG. 5 is a view for describing the alignment of wires of a new solar cell;

FIG. 6 is a perspective view illustrating the heating unit according to an embodiment of the present disclosure;

FIG. 7 is a cross-sectional view of the heating unit for a solar cell of FIG. 6 taken along line IV-IV;

FIG. 8 is an enlarged cross-sectional view of portion A of FIG. 7;

FIG. 9 is a cross-sectional perspective view of the heating unit of FIG. 6 taken along line VI-VI;

FIG. 10 is a perspective view illustrating the cutting unit according to an embodiment of the present disclosure;

FIG. 11 is a perspective view illustrating a cutting unit according to another embodiment of the present disclosure;

FIG. 12 is a perspective view illustrating an aligning unit according to an embodiment of the present disclosure;

FIG. 13 is an exploded perspective view of a gripper part shown in FIG. 12; and

FIG. 14 is a view for describing a coupled state of a first guiding part and a second guiding part.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described later, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described later in detail with reference to the accompanying drawings, and when the embodiments of the present disclosure are described with reference to the drawings, the same or corresponding components are given the same reference numerals, and repetitive descriptions thereof will be omitted.

As the present embodiments allow for various modifications, particular embodiments will be illustrated in the drawings and further described in the detailed description. The effects and features of the present embodiments and the accompanying methods thereof will become apparent from the following description of the contents, taken in conjunction with the accompanying drawings. However, the present embodiments are not limited to the embodiments described later, and may be implemented in various forms.

In order to clearly describe the present disclosure in the drawings, parts which are not related to the description have been omitted, and like reference numerals refer to similar parts throughout the specification.

It will be understood that although the terms “first,” “second,” and the like may be used herein to describe various components, these components should not be limited by these terms. These components are only used to distinguish one component from another.

As used herein, an expression used in the singular encompasses the expression of the plural, unless it has a clearly different meaning in the context.

It will be further understood that the terms “comprises” and/or “comprising” used herein specify the presence of stated features or components, but do not preclude the presence or addition of one or more other features or components.

In the following embodiments, when a unit, area, or component is referred to as being “formed on” another unit, area, or component, it can be directly or indirectly formed on the other unit, area, or component. That is, for example, intervening units, areas, or components may be present.

In the following embodiments, terms such as “connecting” or “coupling” two members do not necessarily mean a direct and/or fixed connection or coupling of the two members, unless the context clearly indicates otherwise, and do not preclude another members from being interposed between the two members.

Sizes of components in the drawings may be exaggerated or reduced for convenience of description. For example, since the size and thickness of each component shown in the drawings are arbitrarily indicated for convenience of description, the following embodiment is not necessarily limited to what is illustrated.

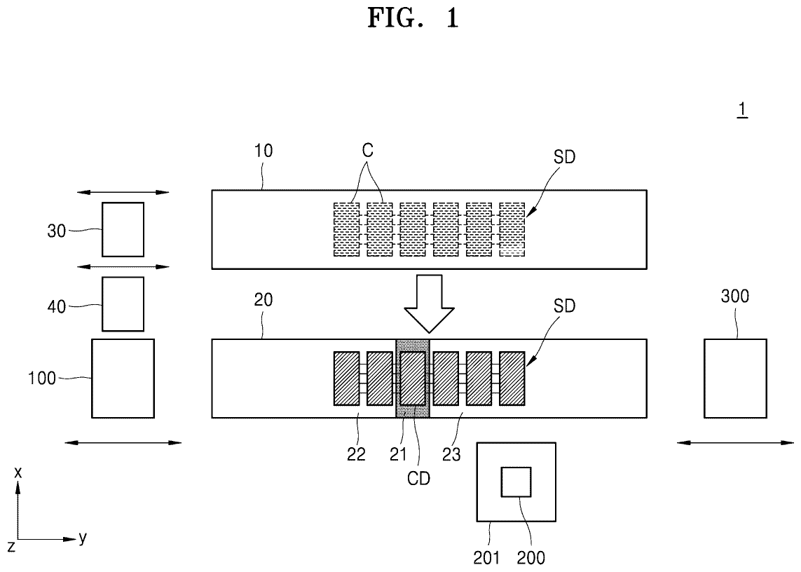

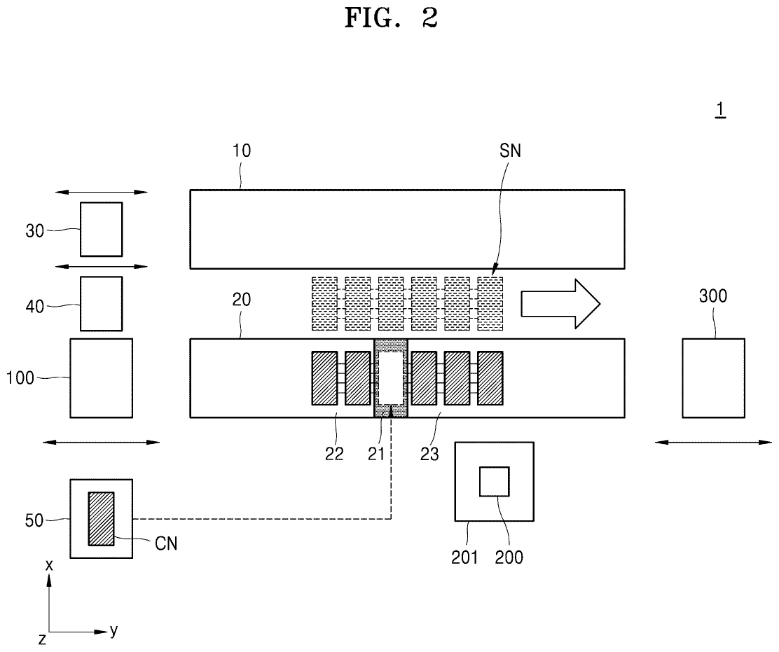

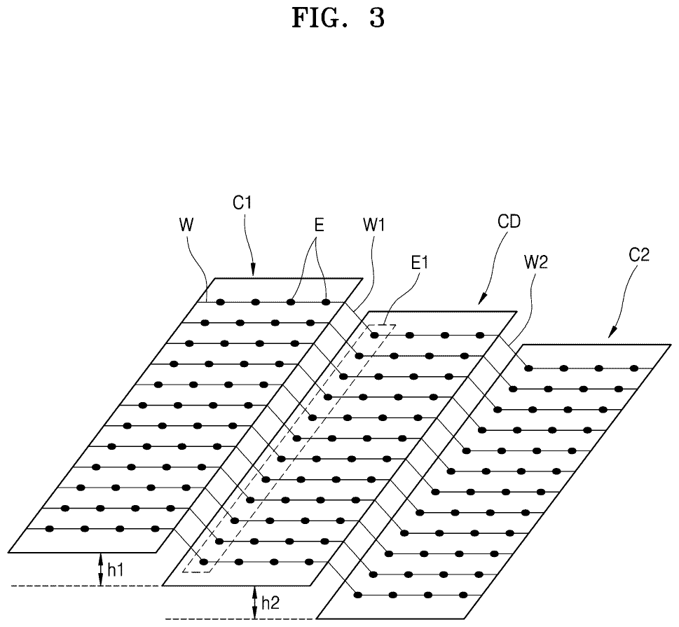

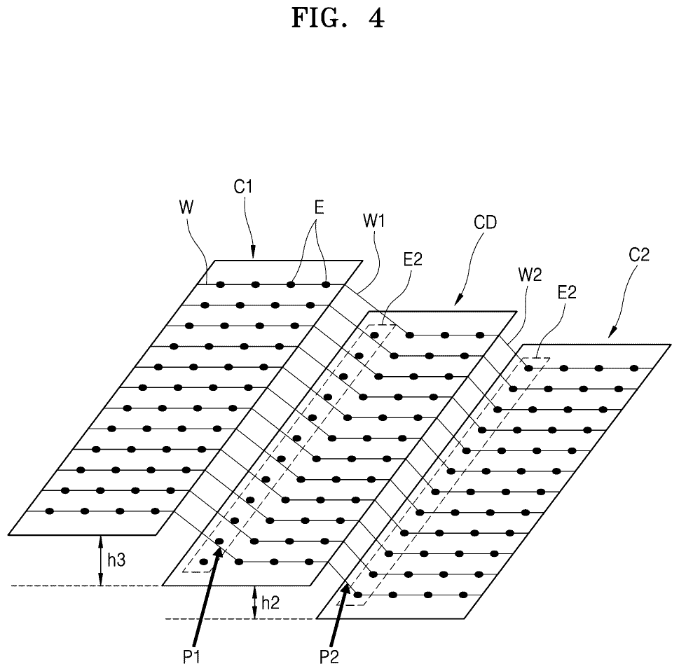

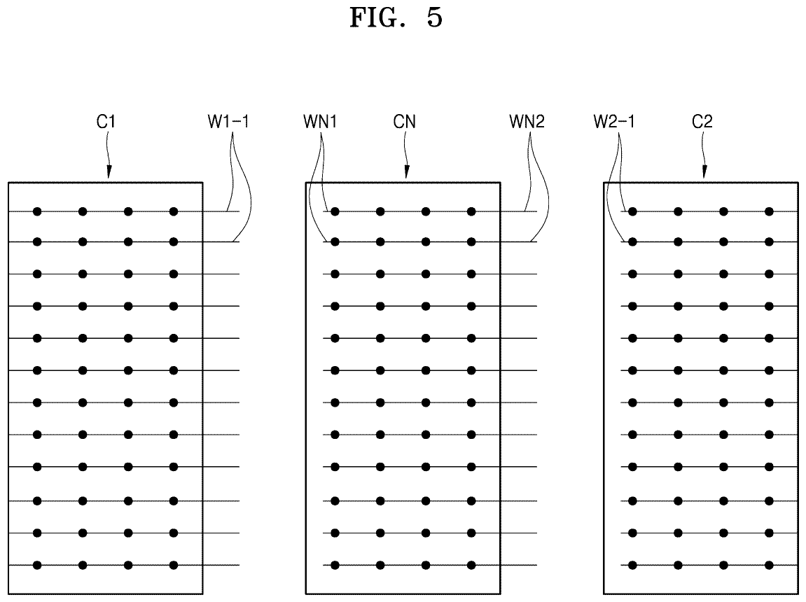

FIGS. 1 and 2 are views for describing a method of replacing a defective cell in a solar cell repairing apparatus 1 according to an embodiment of the present disclosure. FIG. 3 is a view for describing the movement of a stage 20 and a heating position of a heating unit 100, FIG. 4 is a view for describing the movement of the stage 20 and a cutting position of a cutting unit 200, and FIG. 5 is a view for describing the alignment of wires of a repair solar cell CN.

Referring to FIGS. 1 to 5, the solar cell repairing apparatus 1 according to an embodiment of the present disclosure may include the stage 20, the heating unit 100, and the cutting unit 200. The solar cell repairing apparatus 1 may further include an aligning unit 300, an inspection table 10, a first inspection device 30, a second inspection device 40, a soldering device (not shown), and a solar cell moving device (not shown).

The solar cell repairing apparatus 1 may detect and remove a defective cell CD from a solar cell module SD, and perform a repair process on the solar cell module by replacing the defective cell CD with the repair solar cell CN. Further, the solar cell repairing apparatus 1 may automatically perform the repair process on the solar cell module.

As used herein, a solar cell module refers to a string formed of a plurality of solar cells that are electrically connected to each other by wires, and FIG. 1 illustrates an example in which six solar cells are connected to form the solar cell module SD. Adjacent solar cells are electrically connected to each other by wires, and both ends of each of the wires may be connected to electrodes (not shown) positioned on one surface of each of the solar cells.

The wire may be in the form of a wire made of a highly conductive metal material For example, the wire may include a core layer and a coating layer. The core layer may be made of a highly conductive metal material such as Ni, Cu, Ag, or Al, and the coating layer surrounding the core layer may include conductive particles based on Pb or Sn.

In an embodiment, the wire may be coupled to the electrodes of the solar cell by soldering, which involves melting the materials to create a fused connection. In another embodiment, the wire may be attached to the electrodes of the solar cell with a conductive adhesive that is a thermosetting material. However, the present disclosure is not limited to the above-described embodiment, and of course, various known coupling methods may also be applied.

In order to remove the defective cell CD from the solar cell module SD, the wires connected to the defective cell CD need to be cut, and in this case, it is preferable that the wires are cut so that the remaining length of each of the wire after cutting is sufficient to be connected to electrodes of the repair solar cell CN. Accordingly, the solar cell repairing apparatus 1 may include the heating unit 100 to heat an area of electrodes of the defective cell CD, disconnect the connection between the electrodes and the wires, and then cut the wires at a position adjacent to the defective cell CD. Hereinafter, a method of repairing a solar cell module performed by the solar cell repairing apparatus 1 will be described in detail step by step.

The method of repairing a solar cell module performed by the solar cell repairing apparatus 1 according to an embodiment of the present disclosure, includes operation S10 of inspecting the solar cell module SD to detect the defective cell CD, operation S20 of seating the solar cell module SD including the defective cell CD on the stage 20, operation S30 of heating an area of electrodes of the defective cell CD to separate wires from the area of electrodes, operation S40 of cutting the wires between the defective cell CD and adjacent solar cells, and operation S50 of placing the repair solar cell CN, aligning the wires between the adjacent solar cells, and electrically connecting the repair solar cell CN to the adjacent solar cells.

First, in operation S10, the solar cell module SD is inspected to determine whether the defective cell CD is included in the solar cell module SD, and when the defective cell CD is included, a position of the defective cell CD is detected. As shown in FIG. 1, the solar cell module SD may be placed with one surface facing upward on the inspection table 10, and the first inspection device 30 inspects one surface of the solar cell module SD to detect the defective cell CD while moving in a longitudinal direction of the inspection table 10 (e.g., a y direction) along the one surface of the solar cell module SD.

Further, the solar cell module SD may be moved between the inspection table 10 and the stage 20 by a solar cell moving device (not shown), during which the second inspection device 40 inspects another surface of the solar cell module SD to detect the defective cell CD while moving in an arrangement direction of the solar cell module SD (e.g., the y direction) along another surface of the solar cell module SD.

In an embodiment, the solar cell moving device may include a plurality of gripping parts, which may be attached to one surface of each solar cell C to grip each solar cell C. Thus, the solar cell moving device may attach the solar cell module to the gripping parts and move the solar cell module with one surface facing upward, thereby minimizing damage to the solar cell during movement. However, the present disclosure is not limited thereto, and the solar cell module SD may be moved by various moving devices.

Next, in operation S20, when the solar cell module SD includes the defective cell CD, the solar cell module SD is moved to the stage 20 using the solar cell moving device. In this case, the solar cell module SD that is seated on the stage 20 is placed such that the defective cell CD is positioned in a first region 21 of the stage 20.

Next, in operation S30, the heating unit 100 is used to heat the area of the electrodes on one surface of the defective cell CD. The heating unit 100 may include a plurality of spray ports arranged in a line to spray heated air. In this case, the plurality of spray ports may be disposed parallel to a width direction of the stage 20 (e.g., ax x direction). The heating unit 100 may be moved on one surface of the solar cell module SD, which is seated on the stage 20, by a driving device (not shown), and may be moved in a longitudinal direction of the stage 20 (e.g., the y direction).

The heating unit 100 may be moved adjacent to an area of first electrodes E1 of the defective cell CD to heat the area of the first electrodes E1. Here, the first electrodes E1 refer to electrodes that are arranged along one side edge of the defective cell CD, as shown in FIG. 3, and are connected to a first solar cell C1 adjacent thereto by wires.

The heating unit 100 may be positioned at a predetermined distance above the first electrodes E1 to be spaced apart from the first electrodes E1, and may heat the area of the first electrodes E1. That is, the heating unit 100 can spray heated air intensively toward the area of the first electrodes E1 without making contact therewith, and can heat the area of the first electrodes E1.

In the defective cell CD in which the area of the first electrodes E1 is heated by the heating unit 100, the wiring connection of the first electrodes E1 may be disconnected. Here, the term “disconnection of the wire connection” means that the wire that has been coupled to the first electrode E1 by solder or conductive adhesive becomes detached from the first electrode E1 and the coupling between the first electrodes E1 and the wire is released.

Meanwhile, referring to FIGS. 3 and 4 together with FIG. 1, in operation S30, the stage 20 may move a second region 22 upward (e.g., in a z direction) to effectively disconnect the wire connection of the first electrodes E1. Thus, good cells placed in the second region 22 may be positioned higher than the defective cell CD placed in the first region 21, and separation intervals between the defective cell CD and the good cells placed adjacent thereto in the second region 22 may increase.

Further, as the second region 22 moves upward, a third region 23 may move downward in a direction opposite to a movement direction of the second region 22. Through this, good cells placed in the third region 23 may be positioned lower than the defective cell CD placed in the first region 21, and separation intervals between the defective cell CD and the good cells placed adjacent thereto in the third region 23 may increase.

The upward movement of the second region 22 and the downward movement of the third region 23 may occur before the heating unit 100 heats the area of the first electrodes E1, but are not limited thereto, and may also occur simultaneously with the heating of the area of the first electrodes E1 by the heating unit 100, or the two-step movement may occur continuously before and during the heating of the area of the first electrodes E1 by the heating unit 100.

In an embodiment, the movement of the stage 20 may occur in the following two steps. First, as shown in FIG. 3, before the first electrodes E1 are disconnected from the wires, the stage 20 may move the second region 22 upward by h1 to increase separation intervals between the defective cell CD and the first solar cell C1 adjacent thereto, and may move the third region 23 downward by h2 to increase separation intervals between the defective cell CD and a second solar cell C2 adjacent thereto (first step movement). At this time, the upward movement height h1 and the downward movement height h2 may be the same or different from each other.

Meanwhile, for convenience of description, only the defective cell CD and the first and second solar cells C1 and C2 placed adjacent thereto among the solar cell module SD shown in FIG. 1 are illustrated in FIGS. 3 to 5 to describe the movement state of the stage 20. Here, the first solar cell C1 refers to a solar cell placed closer to the first electrodes E1 of the defective cell CD, and the second solar cell C2 refers to a solar cell placed on the opposite side of the first solar cell C1 with respect to the defective cell CD. Meanwhile, the shape, number, and arrangement of electrodes E and a wire W of each solar cell are not limited to those illustrated.

Referring again to FIG. 3 together with FIG. 4, after the above first step movement, the heating unit 100 may approach the first electrodes E1 of the defective cell CD and heat the area of the first electrodes E1. Along with the heating of the area of the first electrodes E1 by the heating unit 100, the second region 22 of the stage 20 may move further upward, and finally, a height difference between the defective cell CD and the first solar cell C1 may increase to h3 (second step movement).

As shown in FIG. 4, after the above-described second step movement, first wires W1 connecting the first solar cell C1 to the defective cell CD may be separated from the first electrodes E1, and the defective cell CD, the first solar cell C1, and the second solar cell C2 may be connected with a height difference while the wires remain connected.

Meanwhile, the solar cell repairing apparatus 1 may further include an inspection device that checks whether the disconnection of the wire connection of the first electrodes E1 is fully completed after the heating process by the heating unit 100 is completed.

Next, in operation S40, the wires between the defective cell CD and the good cell adjacent thereto are cut using the cutting unit 200. The cutting unit 200 may approach the defective cell CD in an oblique direction with respect to one surface of the defective cell CD, and may cut the wires between the defective cell CD and the good cell adjacent thereto.

In an embodiment, the cutting unit 200 may be mounted on a robot arm 201 and may be controlled in movement. The robot arm 201 may control the movement of the cutting unit 200 so that the cutting unit 200 approaches the wires between the defective cell CD and the good cell adjacent thereto, and may control the cutting unit 200 to approach the wires while inclined in the oblique direction with respect to one surface of the defective cell CD during the cutting of the wire. In an embodiment, the robot arm 201 may be a driving device having six degrees of freedom. However, the present disclosure is not limited to thereto, and the movement of the cutting unit 200 may be achieved by various driving devices.

The cutting unit 200 may have a plurality of cutting parts arranged in a line, and thus may simultaneously cut a plurality of wires between the defective cell CD and the good cells adjacent thereto. The plurality of cutting parts may be spaced apart from each other to correspond to separation intervals of the plurality of wires. In this case, the plurality of cutting parts may be provided in a number equal to or less than the number of the wires connecting the defective cell CD to the good cell adjacent thereto, but the present disclosure is not limited thereto.

The cutting unit 200 may cut the wires between the defective cell CD and the good cell adjacent thereto at a position closer to the defective cell than the good cell. Specifically, referring to FIG. 4, when the cutting unit 200 cuts the first wires W1 connecting the defective cell CD to the first solar cell C1 that is a good cell adjacent thereto, the cutting unit 200 may cut the first wires W1 at a position adjacent to where the first wires W1 is connected to the defective cell CD, and may cut the first wires W1 so that the length remaining on the first solar cell C1 side is sufficient to be connected to electrodes of the repair solar cell CN. In an embodiment, the cutting unit 200 may cut the first wires W1 at a first cutting position P1, which is a position adjacent to the point where the first wires W1 is separated from the first electrodes E1.

Further, the cutting unit 200 may cut the wires between the defective cell CD and the good cell adjacent thereto at a position closer to the good cell than the defective cell. Specifically, referring to FIG. 4, when the cutting unit 200 cuts second wires W2 connecting the defective cell CD to the second solar cell C2, which is a good cell adjacent thereto, the cutting unit 200 may cut the second wires W2 at a second cutting position P2, which is a position adjacent to second electrodes E2 where the second wires W2 are connected to the second solar cell C2. After the cutting, the second wires W2 remaining on the second solar cell C2 side may have the minimum length necessary for alignment with the wires of the repair solar cell CN.

Meanwhile, the solar cell repairing apparatus 1 may further include an inspection device that checks whether the cuts at the first cutting position P1 and the second cutting position P2 on the wires connecting the defective cell CD have been fully completed after the cutting process by the cutting unit 200 is completed. In an embodiment, the inspection device may include a camera, and the camera may obtain image information of the cutting position.

Further, the solar cell repairing apparatus 1 may further include a single cutting unit (not shown) that can individually cut the wires at incomplete cut sections. The single cutting unit can move to the incomplete cut sections of the wires and cut the wires at the first cutting position P1 or the second cutting position P2.

The defective cell CD, with all wires cut from the adjacent good cells, may be removed from the solar cell module SD. In an embodiment, the removal of the cut defective cell CD may be performed at the first region 21 of the stage 20. Specifically, the first region 21 of the stage 20 may be rotated around its center in the width direction, and the cut defective cell CD may be removed from the stage 20.

Next, in operation S50, the repair solar cell CN is placed, wires between the repair solar cell CN and the adjacent solar cells are aligned using the aligning unit 300, and then the repair solar cell CN is electrically connected to the adjacent solar cells. The repair solar cell CN, which is a new solar cell being replaced, may be placed in the first region 21 of the stage 20, which is a position where the defective cell CD was removed, by a repair moving device 50.

As shown in FIG. 5, the repair solar cell CN, which is placed in the first region 21, may include electrodes arranged on one surface thereof. In addition, the repair solar cell CN may include first repair wires WN1, which extend outwardly for a short distance from the electrodes arranged on one side, and second repair wires WN2, which extend outwardly for a longer distance from the electrodes arranged on another side that is opposite to the one side. In operation S60 to be described later, the first repair wires WN1 may be connected to first remaining wires W1-1 left on the first solar cell C1, and the second repair wires WN2 may be connected to second remaining wires W2-1 left on the second solar cell C2.

After placing the repair solar cell CN in the first region 21 of the stage 20, the second region 22 and the third region 23 of the stage 20 may be moved to initially align the repair solar cell CN with the good cells adjacent thereto. At this time, the first remaining wires W1-1 connected to the first solar cell C1 may overlap with the repair solar cell CN, and the second repair wires WN2 may overlap with the second solar cell C2.

After the initial alignment, the aligning unit 300 is used to more precisely align the wires between the repair solar cell CN and the first solar cell C1 and the wires between the repair solar cell CN and the second solar cell C2. The aligning unit 300 may be moved on the stage 20 by the driving device (not shown) in the longitudinal direction of the stage 20 (e.g., the y direction), and may be moved close to the solar cell module SD on the stage 20. In this case, the aligning unit 300 may have a surface parallel to one surface of the solar cell module SD and may approach the position of the wires to be aligned.

The aligning unit 300 may include a gripper part to align the wires that overlap between the adjacent solar cells so that the wires are positioned on the same line. Specifically, the aligning unit 300 may move between the first solar cell C1 and the repair solar cell CN to align the first remaining wires W1-1 and the first repair wires WN1 so that they are positioned on the same line, and may again move between the repair solar cell CN and the second solar cell C2 to align the second repair wires WN2 and the second remaining wires W2-1 so that they are positioned on the same line.

After the alignment by the aligning unit 300 is completed, the repair solar cell CN is electrically connected to the adjacent solar cells using the soldering device (not shown). Specifically, after the alignment is completed, the first remaining wires W1-1 overlap the electrodes of the repair solar cell CN, and the soldering device heats the overlapping electrodes to connect the first remaining wires W1-1 to the electrodes of the repair solar cell CN. Further, the second repair wires WN2 overlap the electrodes of the second solar cell C2, and the soldering device heats the overlapping electrodes to connect the second repair wires WN2 to the electrodes of the second solar cell C2.

Meanwhile, the solar cell repairing apparatus 1 may further include an inspection device that checks whether the connection of the wires between the repair solar cell CN and the solar cells adjacent thereto is complete after the alignment process by the aligning unit 300 and the soldering process are completed. In an embodiment, the inspection device may include a camera, and the camera may obtain image information the wire connection position.

Further, the solar cell repairing apparatus 1 may further include a single aligning unit (not shown) that can individually align the wires at incomplete connection sections. The single aligning unit may move to the incomplete connection sections of the wires to align the first remaining wires W1-1 with the first repair wires WN1, or the second remaining wires W2-1 with the second repair wires WN2.

A new solar cell module SN, with the wire connections completed, may be transferred out of the solar cell repairing apparatus 1.

Meanwhile, the solar cell repairing apparatus 1 according to an embodiment of the present disclosure may further include a control part (not shown). The control part may control each of the components of the solar cell repairing apparatus 1. The control part may obtain movement information, image information, or the like from each of the components, and may control each of the components using the obtained information. The control part may include a processor for performing the process.

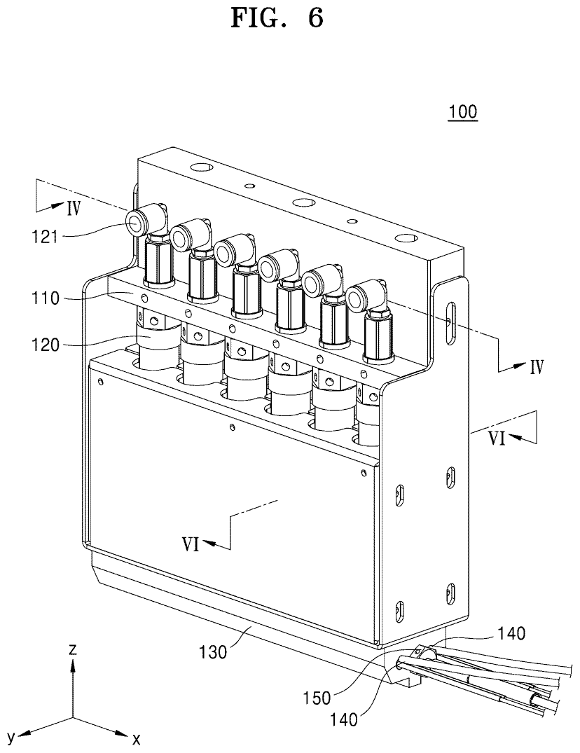

Hereinafter, with reference to FIGS. 6 to 14, the heating unit 100, the cutting unit 200, and the aligning unit 300 included in the solar cell repairing apparatus 1 will be described in more detail.

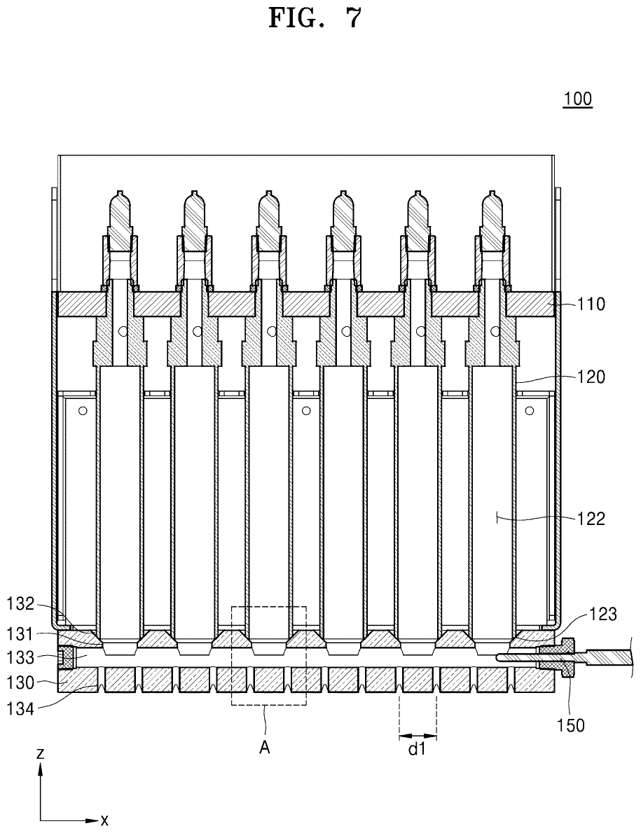

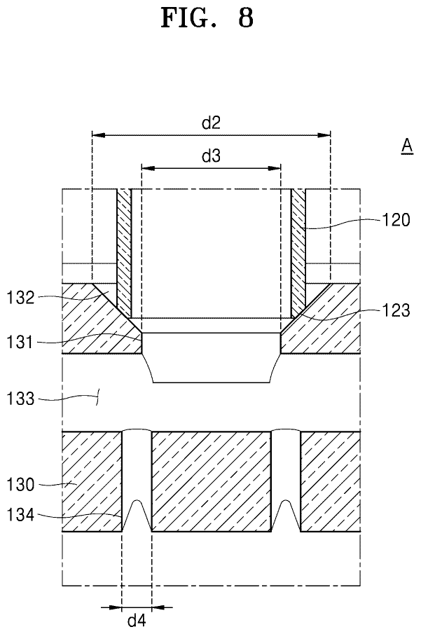

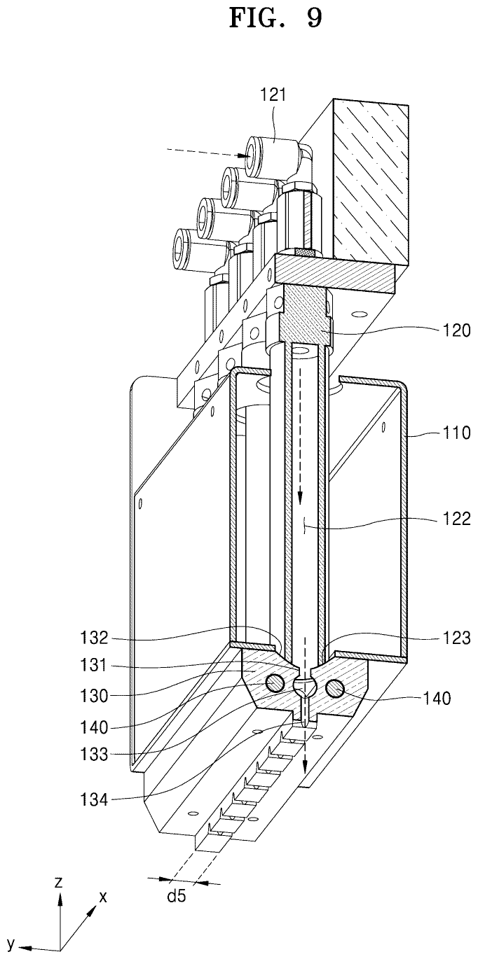

FIG. 6 is a perspective view illustrating the heating unit 100 according to an embodiment of the present disclosure, FIG. 7 is a cross-sectional view of the heating unit 100 for a solar cell of FIG. 6 taken along line IV-IV, FIG. 8 is an enlarged cross-sectional view of portion A of FIG. 7, and FIG. 9 is a cross-sectional perspective view of the heating unit 100 of FIG. 6 taken along line VI-VI.

Referring to FIGS. 6 to 9, the heating unit 100 according to an embodiment of the present disclosure may include a housing 110 forming an exterior, a plurality of air heaters 120 arranged inside the housing 110, and a heating block 130 that sprays heated gas.

The heating unit 100 may be disposed adjacent to the area of the electrodes disposed on one surface of the solar cell to heat the area of the electrodes, and in particular, may heat the first electrodes E1 of the defective cell CD to separate some of the wires from the defective cell CD.

The housing 110 may form the exterior of the heating unit 100. A space in which the air heaters 120 are installed may be formed in the housing 110. The housing 110 may support the plurality of air heaters 120 and may serve to protect the human body from a high-temperature generating part.

The air heaters 120 are devices capable of heating gas, and may be installed in the housing 110. A plurality of air heaters 120 may be provided and arranged inside the housing 110 in a first direction, which is a longitudinal direction of the housing (e.g., the x direction).

Each of the air heaters 120 may protrude outward from the housing and may include one end portion 121 through which gas is introduced, a hollow part 122 that is a moving path of gas, and another end portion 123 through which gas is sprayed. The air heater 120 may heat gas introduced thereinto through the one end portion 121, and discharge the gas through the another end portion 123.

The heating block 130 may be disposed on one side of the housing 110, and may be coupled to the another end portions 123 of the air heaters 120. The heating block 130 may include a plurality of inlet ports 131 and a plurality of spray ports 134, may concentrate gas, which is heated by the air heater 120 and sprayed, to spray the gas to the outside.

Meanwhile, the heating block 130 is spaced apart from the first electrodes E1 of the defective cell CD by a certain distance and may spray heated gas onto the area of the first electrodes E1. In other words, the heating block 130 can locally heat the area of the first electrodes E1 by spraying heated gas toward the first electrodes E1 without making contact with the first electrodes E1.

The plurality of inlet ports 131 may be formed to correspond to the air heaters 120. Specifically, the plurality of inlet ports 131 may be formed at positions corresponding to positions of the air heaters 120, and may be formed in a number equal to the number of the air heaters 120.

Each of the inlet ports 131 may include an inclined portion 132 on which the another end portion 123 of the air heater 120 is seated. The inclined portion 132 may be formed such that an outer diameter d2 thereof is greater than a diameter of the another end portion 123 of the air heater 120, and an inner diameter d3 thereof is smaller than the diameter of the another end portion 123 of the air heater 120. With the inclined portion 132, the gas sprayed from the another end portion 123 of the air heater 120 may be effectively introduced into the inlet port 131. In this case, the another end portion 123 of the air heater 120 may be formed with the same inclination as the inclined portion 132.

An accommodation space 133 may be formed between the plurality of inlet ports 131 and the plurality of spray ports 134. The accommodation space 133 may be in communication with all of the plurality of inlet ports 131 and the plurality of spray ports 134, and may serve to distribute gases introduced through the plurality of inlet ports 131 to the plurality of spray ports 134.

The plurality of spray ports 134 may be provided to be in communication with the plurality of inlet ports 131, but may be provided in a number different from the number of the plurality of inlet ports 131. In an embodiment, the number of the plurality of spray ports 134 may be greater than the number of the plurality of inlet ports 131. Further, the number of the plurality of spray ports 134 may be configured to correspond to the number of rows of electrodes arranged in the longitudinal direction among the electrodes formed on one surface of the solar cell.

The plurality of spray ports 134 may be spaced apart from each other by a predetermined distance d1, which may be configured to correspond to the separation distance of the electrodes, which are formed on one surface of the solar cell, in the longitudinal direction. The heating unit 100 can simultaneously heat a plurality of electrodes included in a single row of electrodes of the solar cell by arranging the plurality of spray ports 134 to correspond to the separation distance of the electrodes.

A diameter d4 of the spray port 134 may be smaller than a diameter of each of the plurality of inlet ports 131, which is defined by the inner diameter d3 of the inclined portion 132. Further, the spray port 134 may be formed in a size corresponding to the size of the electrode formed on one surface of the solar cell. Through this, the heating unit 100 can spray the air heated by the air heater 120 in a concentrated manner onto the area of the electrodes of the solar cell, and prevent unnecessary areas from being heated.

The heating unit 100 may further include a cartridge heater 140 inserted into the heating block 130, as well as a temperature sensor 150 and a heating control part The cartridge heater 140 may extend in the first direction in which the air heaters 120 are arranged, and may be inserted into the heating block.

The cartridge heater 140 is disposed adjacent to the accommodation space 133 of the heating block 130, and can further heat the already heated gas introduced into the accommodation space 133. A plurality of cartridge heaters 140 may be provided and symmetrically disposed with respect to the accommodation space.

Referring to the arrow in FIG. 9, gas introduced into the interior of the heating unit 100 through the one end portion 121 of the air heater 120 moves along the hollow part 122, gets heated, then passes through the accommodation space 133 of the heating block 130, and is discharged to the outside through the spray ports 134. At this time, the heated gas that has been initially heated by the air heater 120 may move to the heating block 130 and then heated once more by the cartridge heater 140.

Meanwhile, based on the measurement value of the temperature sensor 150, the cartridge heater 140 can heat the accommodation space 133 and maintain the temperature of the heated gas in the accommodation space 133 above a certain temperature. The heating control part may obtain heat distribution information of the heating block 130 via the temperature sensor 150 and control the air heater 120 and the cartridge heater 140 based on this information.

By spraying heated air in a concentrated manner onto the first electrodes E1 of the defective cell CD, the heating unit 100 can effectively heat the area of the first electrodes E1 and prevent damage to the solar cell module during the heating process. In addition, the heating unit 100 can significantly reduce the operation time by allowing the electrodes included in the first electrodes E1 to be heated simultaneously.

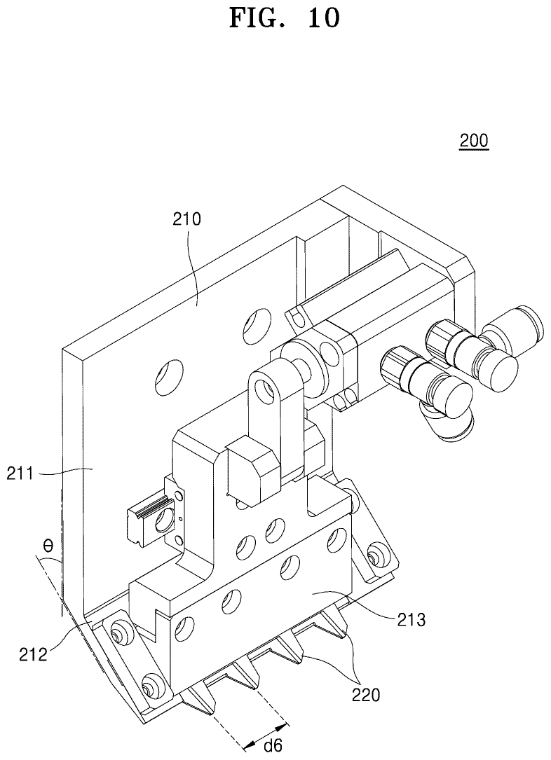

FIG. 10 is a perspective view illustrating the cutting unit 200 according to an embodiment of the present disclosure.

Referring to FIG. 10, the cutting unit 200 according to an embodiment of the present disclosure may include a body part 210 and a cutting part 220. The cutting unit 200 may cut the wires connecting the good cell adjacent to the defective cell CD to the defective cell CD.

The cutting unit 200 may cut the wires, which are separated from the defective cell CD by the heating unit 100, at a position adjacent to the defective cell CD. In other words, the cutting unit 200 may cut the first wires W1, which are separated from the first electrodes E1 by heating the area of the first electrodes E1 of the defective cell CD, at the first cutting position P1, which is a position closer to the defective cell CD than the good cell. Further, the cutting unit 200 may cut the wires, which connect the defective cell CD to the good cell placed farther away from the first electrodes E1 among the good cells adjacent to the defective cell CD, at a position adjacent to the good cell. That is, the cutting unit 200 may cut the second wires W2, which connect the defective cell CD to the good cell, at the second cutting position P2 that is a position closer to the good cell. The cutting unit 200 may be configured to cut the wires positioned between the defective cell CD and the adjacent good cell so that one side of the remaining wire is left long enough to be connected to the electrode of the new solar cell after cutting, while the other side of the remaining wire is left short after cutting.

In an embodiment, the cutting unit 200 may be mounted on the robot arm 201 having six degrees of freedom. However, the present disclosure is not limited thereto, and the cutting unit 200 may be mounted on various driving devices. However, for convenience of description, the following description will focus on an embodiment in which the cutting unit 200 is mounted on the robot arm 201.

The body part 210 serves to fix the cutting unit 200 to the robot arm 201, and may have one end to which the cutting part 220 is connected. The body part 210 may include a first body part 211 extending in one direction and a second body part 212 extending in a direction forming a predetermined angle θ with a direction in which the first body part 211 extends, and may further include a cover part 213 that supports the cutting part 220.

By configuring the body part 210 so that the first body part 211, which is connected to the robot arm 201, and the second body part 212, to which the cutting part 220 is connected, form a predetermined angle, the cutting part 220 can approach the solar cell module SD in an oblique direction with respect to one surface of the defective cell CD, thereby facilitating the cutting of the wires. Here, the term “oblique direction” means that the direction in which the cutting part 220 extends forms a predetermined angle with a direction in which one surface of the defective cell CD extends. Meanwhile, the robot arm 201 may control the cutting unit 200 so that the cutting unit 200 approaches the defective cell CD in the oblique direction with respect to one surface of the defective cell CD when cutting the wires. Through this, the cutting unit 200 can remove the defective cell CD from the solar cell module SD with minimal damage to the good cells.

A plurality of cutting parts 220 may be provided and spaced apart from each other by a predetermined distance d6. The distance d6 by which the plurality of cutting parts 220 are spaced apart from each other may correspond to the wiring interval of the solar cell module.

In an embodiment, the number of the cutting parts 220 may be less than the number of the wires of the solar cell module SD. For example, when the solar cell module SD includes 12 wires, the cutting part 220 may be provided in quantities that are factors of 12, such as 2, 3, 4, or 6. The cutting unit 200 having four cutting parts 220 may cut the wires on one side surface connected to the defective cell CD in three cuts, thereby reducing the operation time.

The cutting unit 200 may further include a cutting control part. The cutting control part may control the movement of the cutting unit 200 by controlling the drive of the robot arm.

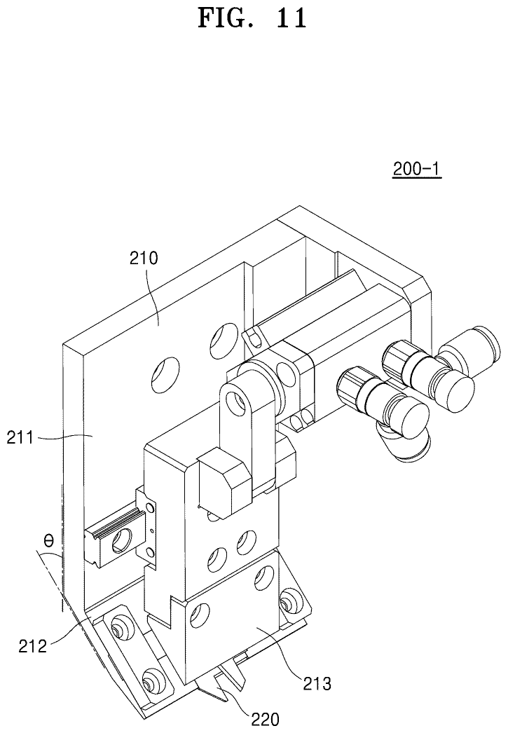

FIG. 11 is a perspective view illustrating a cutting unit 200-1 according to another embodiment of the present disclosure.

Referring to FIG. 11, the cutting unit 200-1 may include a body part 210 having a first body part 211 and a second body part 212, a cutting part 220, and a cover part 230.

The cutting unit 200-1 of FIG. 11 is different from the cutting unit 200 according to the embodiment described with reference to FIG. 10 in that the cutting unit 200-1 includes a single cutting part 220. The solar cell repairing apparatus 1 may include two cutting units 200 and 200-1, where the wires are initially cut by the cutting unit 200 and then further cut by the cutting unit 200-1.

Specifically, in the solar cell repairing apparatus 1, once the wires have been cut by the cutting unit 200 including the plurality of cutting parts 220, the inspection device is used to check the cut position. When an incomplete cut wire is found, the solar cell repairing apparatus 1 can use the cutting unit 200-1, which includes one cutting part 220, to individually cut only the incompletely cut section, thereby completely cutting the connection wires of the defective cell CD. At this time, the cutting control part may obtain image information of the cutting position from the control part or the inspection device of the solar cell repairing apparatus 1, and control the cutting unit 200 and the single cutting unit 200-1 based on this information.

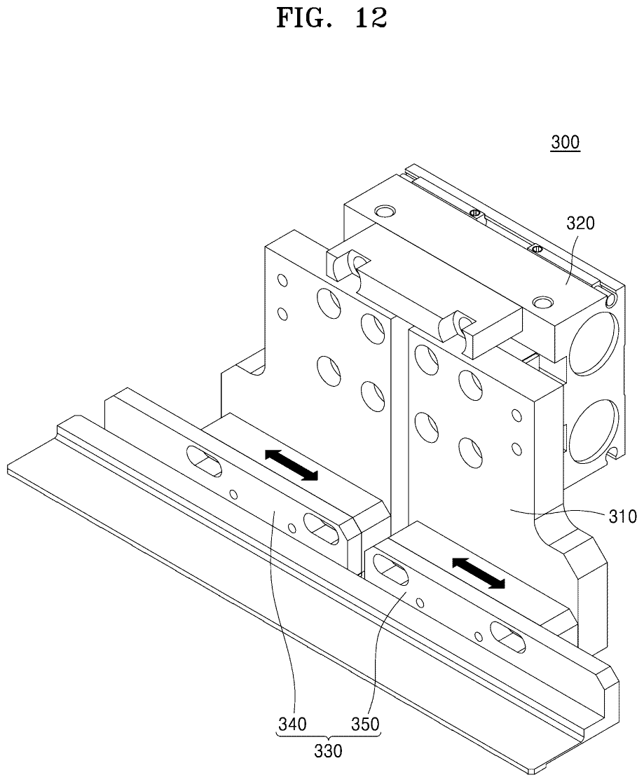

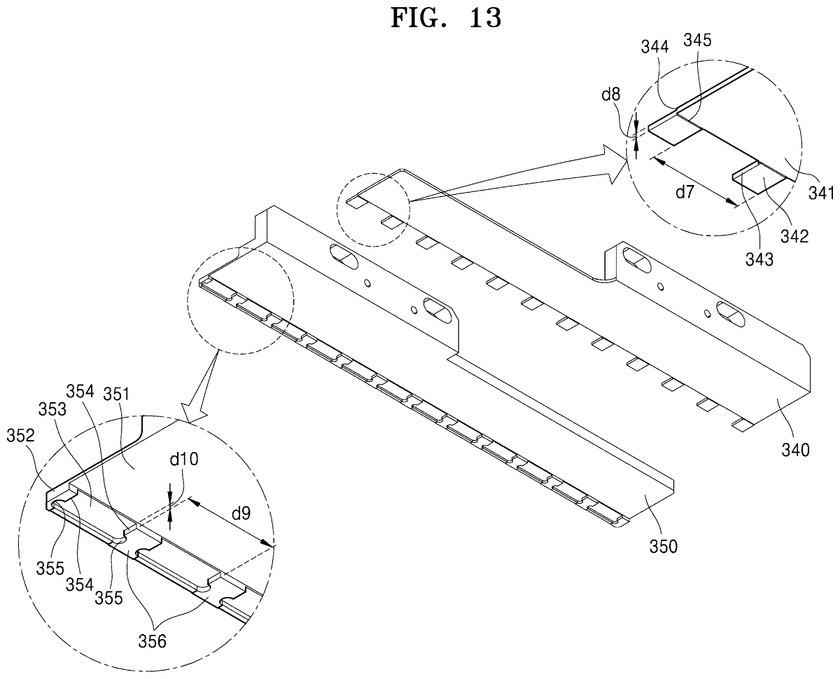

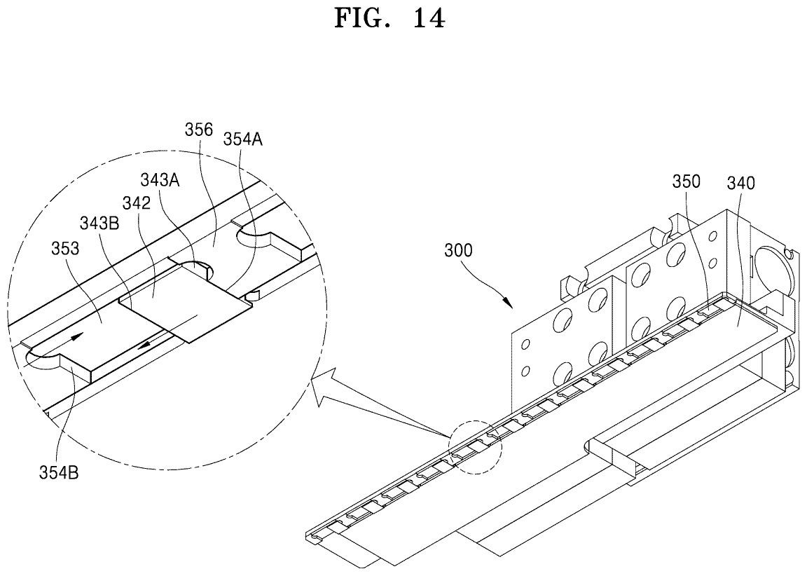

FIG. 12 is a perspective view illustrating the aligning unit 300 according to an embodiment of the present disclosure, FIG. 13 is an exploded perspective view of a gripper part 330 shown in FIG. 12, and FIG. 14 is a view for describing a coupled state of a first guiding part 342 and a second guiding part 356.

Referring to FIGS. 12 to 14, the aligning unit 300 according to an embodiment of the present disclosure may include a mounting part 310 and the gripper part 330 coupled to one end of the mounting part 310, and may further include an air cylinder 320.

The aligning unit 300 may align the wires between the new solar cell CN, which replaces the defective cell in the solar cell module SD, and the adjacent good cells. The solar cell module SD from which the defective cell CD has been removed by the cutting unit 200 still includes remaining wires that have been cut, and after placing the new solar cell CN, it is necessary to connect the remaining wires to the new solar cell CN. The aligning unit 300 may align the wires between the new solar cell CN and the first and second solar cells C1 and C2 placed adjacent thereto at the electrode positions to prepare for the soldering operation.

The mounting part 310 may be mounted to the driving device and may be coupled on the air cylinder 320 that sets a precise stroke.

The gripper part 330 may be coupled to one end of the mounting part 310 and may reciprocate within a predetermined range. The gripper part 330 may be disposed parallel to one surface of the solar cell module when aligning the wires. The gripper part 330 may include a first gripper part 340 and a second gripper part 350.

The first gripper part 340 may include a first plate 341 extending in one direction and the first guiding part 342 protruding from one end of the first plate 341. The first guiding part 342 may have a preset first thickness d8.

The first guiding part 342 may be disposed to form a first step 344 with one surface of the first plate 341. The first step 344 may serve as a stopper when the first gripper part 340 is coupled to the second gripper part 350. Further, the first guiding part 342 may be disposed to form a second step 345 with another surface of the first plate 341. The second step 345 may serve to form a separation space between the first plate 341 and the solar cell.

A plurality of first guiding parts 342 may be provided and disposed along an edge of the first plate 341 to be spaced apart from each other by a predetermined distance d7. The distance d7 by which the plurality of first guiding parts 342 are spaced apart from each other may be set to correspond to the distance between the wires of the solar cell module.

The second gripper part 350 may include a second plate 351 extending in a direction parallel to the first plate 341 of the first gripper part 340 and the second guiding part 356 formed at an end portion 352 of the second plate 351. The second guiding part 356 may have a preset second thickness d10, and a groove 355 may be formed on each of both side surfaces 354 of the second guiding part 356.

In an embodiment, the first thickness d8 of the first guiding part 342 may be the same as the second thickness d10 of the second guiding part 356, but the present disclosure is not limited thereto.

Meanwhile, the first thickness d8 of the first guiding part 342 and the second thickness d10 of the second guiding part 356 may be determined according to a thickness of the wire. In an embodiment, the first thickness d8 of the first guiding part 342 or the second thickness d10 of the second guiding part 356 may be determined within a thickness range of 30% to 60% of the thickness of the wire. When the first thickness d8 of the first guiding part 342 or the second thickness d10 of the second guiding part 356 is less than 30% of the thickness of the wire, it may be difficult to grip the wire using the first and second guiding parts 342 and 356. When the first thickness d8 of the first guiding part 342 or the second thickness d10 of the second guiding part 356 exceeds 60% of the thickness of the wire, there is a risk of causing defects by coming into contact with the solar cell CN during the process of aligning the wires. For example, when the wire is about 0.26 mm in thickness, the first thickness d8 of the first guiding part 342 or the second thickness d10 of the second guiding part 356 may be determined to be about 0.1 mm.

A plurality of second guiding parts 356 may be provided and disposed along an edge of the second plate 351 to be spaced apart from each other by a predetermined distance d9. A groove 353 may be formed between two adjacent second guiding parts 356.

The second gripper part 350 may move relative to the first gripper part 340, and the wires may be aligned by the first guiding parts 342 of the first gripper part 340 and the second guiding parts 356 of the second gripper part 350. Specifically, when the first gripper part 340 is coupled to the second gripper part 350, the first guiding part 342 is disposed in the groove 353, and the wire may be placed between one side surface 343A of the first guiding part 342 and one side surface 354A of the second guiding part 356.

That is, the first remaining wires W1-1 of the first solar cell C1 and the first repair wires WN1 of the repair solar cell CN adjacent thereto may be placed together and aligned between the first guiding parts 342 and the second guiding parts 356. In addition, the second repair wires WN2 and the second remaining wires W2-1 of the second solar cell C2 adjacent thereto may be placed together and aligned between the first guiding parts 342 and the second guiding parts 356.

Accordingly, the aligning unit 300 can precisely align the wires while minimizing damage to the solar cells through the first guiding part 342 and the second guiding part 356, which are provided to engage with each other.

In another embodiment, the aligning unit 300 may include a first gripper part 340 having a single first guiding part 342 and a second gripper part 350 having a single second guiding part 356. This single aligning unit 300 can individually align a single wire. The solar cell repairing apparatus 1 may include both the above-described single aligning unit 300 and the aligning unit 300 including a plurality of guiding parts.

Once the initial alignment is completed by the aligning unit 300 including a plurality of guiding parts, the solar cell repairing apparatus 1 may inspect the alignment of the wires using the inspection device and detect improperly aligned areas. When there are improperly aligned wires, the improperly aligned wires can be individually aligned using the single aligning unit 300 including a single guiding part.

The aligning unit may further include an alignment control part. The alignment control part may obtain image information of the alignment position from the control part or the inspection device of the solar cell repairing apparatus 1 and control the aligning unit 300 and the single aligning unit 300 based on this information.

As described above, the solar cell repairing apparatus 1 according to an embodiment of the present disclosure includes the heating unit 100, the cutting unit 200, and the aligning unit 300, allowing defective cells to be quickly and easily replaced in the solar cell module, thereby reducing the costs and time required for the operation.

In addition, the solar cell repairing apparatus 1 eliminates the need for manual labor, thereby preventing additional damage to the solar cells during operation and enabling precise work.

Further, the heating unit 100 according to an embodiment of the present disclosure can quickly and effectively heat the area of electrodes of the solar cell by spraying heated gas in a concentrated manner onto the area of the electrodes of the solar cell, and can easily separate the wires from the electrodes of the solar cell.

Further, the cutting unit 200 according to an embodiment of the present disclosure can approach the wires in an oblique direction with respect to the solar cell during the cutting of the wires, thereby preventing damage to the solar cells, and can quickly and effectively cut the wires to remove the defective cell.

Further, the aligning unit 300 according to an embodiment of the present disclosure includes two interlocking guiding parts, thereby allowing for precise alignment of the wires between solar cells and accurately connecting a new solar cell to the correct position.

As such, the present disclosure has been described with reference to the embodiments shown in the drawings, but it will be understood that this are merely exemplary, and those of ordinary skill in the art will understand that various modifications and variations of the embodiments are possible therefrom. Accordingly, the true technical scope of the present disclosure is defined by the technical spirit of the appended claims.

A heating unit according to embodiments of the present disclosure can effectively heat an area of electrodes of a solar cell by spraying hot air in a concentrated manner onto the area of electrodes of the solar cell, thereby minimizing damage to the solar cell and reducing operation time.

Further, a solar cell repairing apparatus according to embodiments of the present disclosure includes a cutting unit with six-axis degrees of freedom, which can minimize damage to solar cells during the cutting of wires connecting the solar cells to each other and reduce operation time.

Further, a solar cell repairing apparatus according to embodiments of the present disclosure includes an aligning unit that aligns wires of a newly replaced solar cell, thereby enabling precise adjustment of wire positions and reducing operation time.

Further, a solar cell repairing apparatus according to embodiments of the present disclosure facilitates the easy replacement of a defective cell in a solar cell module through an automated process, thereby reducing costs and time and minimizing damage to solar cells during a repair process, which can enhance convenience and productivity.

Of course, the scope of the present disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A heating unit for a solar cell, the heating unit comprising:
a housing forming an exterior;
a plurality of air heaters arranged in a first direction in the housing; and
a heating block disposed on one side of the housing and configured to spray gas heated by the plurality of air heaters to an outside the heating unit in a concentrated manner,
wherein the heating block includes:
a plurality of inlet ports formed at positions corresponding to the plurality of air heaters; and
a plurality of spray ports being in communication with the plurality of inlet ports, spaced apart from each other predetermined intervals, and each having a diameter smaller than a diameter of each of the inlet ports.

2. The heating unit of claim 1, wherein a number of the inlet ports and a number of the spray ports are different from each other.

3. The heating unit of claim 1, wherein a number of the spray ports is greater than a number of the inlet ports.

4. The heating unit of claim 1, wherein the plurality of spray ports are spaced apart from each other to correspond to separation distances of electrodes formed on one surface of a solar cell.

5. The heating unit of claim 4, wherein each of the spray ports is formed to correspond in size to a size of each of the electrodes.

6. The heating unit of claim 1, further comprising a cartridge heater extending in the first direction and inserted into the heating block.

7. The heating unit of claim 6, wherein
the heating block further includes an accommodation space formed between the inlet ports and the spray ports, and
the cartridge heater is disposed adjacent to the accommodation space.

8. The heating unit of claim 7, wherein
the cartridge heater is provided as a plurality of cartridge heaters, and
the plurality of cartridge heaters are symmetrically disposed with respect to the accommodation space.

9. A solar cell repairing apparatus comprising:
a stage configured to support a solar cell module that includes a plurality of solar cells connected to each other by wires;
a heating unit configured to heat an area of first electrodes of a defective cell in the solar cell module to separate some of the wires from the defective cell; and
a cutting unit configured to cut wires that connect the defective cell to a good cell adjacent to the defective cell,
wherein the heating unit includes:
a housing forming an exterior;
a plurality of air heaters arranged in a first direction in the housing; and
a heating block disposed on one side of the housing and configured to spray gas heated by the plurality of air heaters to an outside of the heating unit in a concentrated manner,
wherein the heating block includes:
a plurality of inlet ports formed at positions corresponding to the plurality of air heaters; and
a plurality of spray ports being in communication with the plurality of inlet ports, spaced apart from each other predetermined intervals, and each having a diameter smaller than a diameter of each of the inlet ports.

10. The solar cell repairing apparatus of claim 9, wherein the heating block is spaced apart from the first electrodes by a predetermined distance and configured to spray the heated gas onto the area of the first electrodes.

11. The solar cell repairing apparatus of claim 9, wherein the cutting unit cuts the wires, which are separated from the defective cell, at a position adjacent to the defective cell than the good cell.

12. The solar cell repairing apparatus of claim 9, wherein
a movement of the cutting unit is controlled by a robot arm; and
the robot arm controls the movement of the cutting unit so that the cutting unit approaches the defective cell in an oblique direction with respect to one surface of the defective cell during the cutting of the wires.

13. The solar cell repairing apparatus of claim 9, further comprising an aligning unit configured to align wires between a solar cell replacing the defective cell and the good cell.

14. The solar cell repairing apparatus of claim 13, wherein the aligning unit includes:
a mounting part mounted on a driving device; and
a gripper part coupled to one end of the mounting part,
wherein the gripper part includes a first gripper including a first guiding part having a preset first thickness, and a second gripper including a second guiding part that has a preset second thickness and moves relative to the first gripper, and
wherein the first thickness and the second thickness are determined according to a thickness of each of the wires.
